(19) United States
(12) Patent Application Publication
(10) Pub. No.: US 2024/0279505 A1
(43) Pub. Date: Aug. 22, 2024

(54) COMPOSITION, METAL-CONTAINING FILM, METAL-CONTAINING FILM FORMATION METHOD, AND COMPOSITION PRODUCTION METHOD

(71) Applicant: JSR CORPORATION, Tokyo (JP)

(72) Inventor: Yuusuke OOTSUBO, Tokyo (JP)

(73) Assignee: JSR CORPORATION, Tokyo (JP)

(21) Appl. No.: 18/632,646

(22) Filed: Apr. 11, 2024

Related U.S. Application Data
(63) Continuation-in-part of application No. PCT/JP2022/037424, filed on Oct. 6, 2022.

(30) Foreign Application Priority Data
Oct. 14, 2021 (JP) 2021-168664

(51) Int. Cl. C09D 159/04; C09D 1/00; C09D 5/24

(52) U.S. Cl. CPC C09D 159/04; C09D 1/00; C09D 5/24

(57) ABSTRACT

A composition includes: a metal compound; a compound having an oxymethylene structure; and a solvent. The metal compound is a metal salt or a metal complex. The compound having an oxymethylene structure is capable of generating an aldehyde structure when degraded through heating. A metal atom contained in the metal compound preferably belongs to any one of periods 3 to 7 among groups 2 to 14 in a periodic table.

### CROSS-REFERENCE TO RELATED APPLICATIONS

The present application is a continuation-in-part application of International Patent Application No. PCT/JP2022/037424 filed Oct. 6, 2022, which claims priority to Japanese Patent Application No. 2021-168664 filed Oct. 14, 2021. The contents of these applications are incorporated herein by reference in their entirety.

### BACKGROUND OF THE DISCLOSURE

### Technical Field

The present disclosure relates to a composition, a metal-containing film, a method for forming a metal-containing film, and a method for producing a composition.

### Background Art

In the production of a semiconductor device, used is a method for forming a metal-containing film on a substrate through chemical vapor deposition (CVD) using an organic metal precursor or through atomic layer deposition (ALD) (see WO 2011/017068 A). A technique is proposed in which a metal-containing composition is applied onto a substrate and heated to form a metal-containing film (see JP-A-2005-002418).

### SUMMARY

According to an aspect of the present disclosure, a composition includes: a metal compound; a compound having an oxymethylene structure; and a solvent. The metal compound is a metal salt or a metal complex. The compound having an oxymethylene structure is capable of generating an aldehyde structure when degraded through heating.

According to another aspect of the present disclosure, a metal-containing film is formed from a composition. The composition includes: a metal compound; a compound having an oxymethylene structure; and a solvent. The metal compound is a metal salt or a metal complex. The compound having an oxymethylene structure is capable of generating an aldehyde structure when degraded through heating.

According to a further aspect of the present disclosure, a method for forming a metal-containing film includes applying a composition directly or indirectly onto a substrate to form a coating film. The composition includes: a metal compound; a compound having an oxymethylene structure; and a solvent. The metal compound is a metal salt or a metal complex. The compound having an oxymethylene structure is capable of generating an aldehyde structure when degraded through heating.

According to a further aspect of the present disclosure, a method for producing a composition for forming a metal-containing film, includes mixing a metal compound, a compound having an oxymethylene structure, and a solvent. The metal compound is a metal salt or a metal complex. The compound having an oxymethylene structure is capable of generating an aldehyde structure when degraded through heating.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In an embodiment of the present disclosure, a composition for forming a metal-containing film, includes: a metal compound; a compound having an oxymethylene structure (hereinafter, it is also referred to as “compound (I)”); and a solvent. Compound (I) decomposes or depolymerizes to produce a aldehyde structure having a reducing power, which reduces the metal atoms in the metal compound and promotes the formation of metal-containing films, thereby improving film continuity and conductivity.

According to the composition for forming a metal-containing film, it is possible to form a metal-containing film with excellent conductivity. Although the reason for this is not certain, it is inferred as follows. A metal-containing film is formed by heating the coating film of the composition for forming the metal-containing film. At that time, compound (I) decomposes or depolymerizes to produce a reducing aldehyde structure, which reduces the metal atoms of the metal compound and promotes the formation of the metal-containing film, thereby improving the continuity and conductivity of the film.

In another embodiment of the present disclosure, a metal-containing film formed from a composition for forming a metal-containing film. The composition includes: a metal compound; a compound having an oxymethylene structure; and a solvent. The metal compound is a metal salt or a metal complex, and the compound having an oxymethylene structure is a compound that generates an aldehyde structure when degraded through heating.

According to the metal-containing film, it can exhibit excellent electrical conductivity since it is formed from the composition for forming a metal-containing film.

In a further embodiment of the present disclosure, a method for forming a metal-containing film includes directly or indirectly coating a substrate with a composition for forming a metal-containing film. The composition includes: a metal compound; a compound having an oxymethylene structure; and a solvent. The metal compound is a metal salt or a metal complex, and the compound having an oxymethylene structure is a compound that generates an aldehyde structure when degraded through heating.

According to the method for forming a metal-containing film, a metal-containing film with excellent conductivity can be efficiently formed.

In a further embodiment of the present disclosure, a method for producing a composition for forming a metal-containing film, includes mixing a metal compound, a compound having an oxymethylene structure, and a solvent. The metal compound is a metal salt or a metal complex, and the compound having an oxymethylene structure is a compound that generates an aldehyde structure when degraded through heating.

According to the method for producing a composition for forming a metal-containing film, a composition suitable for forming metal-containing films which can form a metal-containing films with excellent conductivity can be produced.

### <Composition for Forming Metal-Containing Film>

The composition for forming a metal-containing film contains a metal compound, a compound (I), and a solvent. The composition for forming a metal-containing film may contain an optional component as long as the effect of the present invention is not impaired. Hereinafter, the components contained in the composition for forming a metal-containing film are described.

### [Metal Compound]

The metal compound is not particularly limited as long as the metal compound contributes to the formation of a metal-containing film by heating a coating film formed from the composition for forming a metal-containing film, and any organic or inorganic known metal compound can be used. The metal compound is preferably a metal salt, a metal complex, or a combination of the metal salt and the metal complex. The metal salt and the metal complex include hydrates thereof.

Examples of a metal atom contained in the metal compound include a metal atom belonging to any one of periods 3 to 7 among groups 2 to 14 in the periodic table. The metal compound may contain at least one type of metal atom.

Examples of a group 2 metal atom include magnesium, calcium, strontium, and barium;

examples of a group 3 metal atom include atoms belonging to lanthanoids such as scandium, yttrium, and lanthanum, and atoms belonging to actinoids such as actinium;

examples of a group 4 metal atom include titanium, zirconium, and hafnium;

examples of a group 5 metal atom include vanadium, niobium, and tantalum;

examples of a group 6 metal atom include chromium, molybdenum, and tungsten;

examples of a group 7 metal atom include manganese and rhenium;

examples of a group 8 metal atom include iron, ruthenium, and osmium;

examples of a group 9 metal atom include cobalt, rhodium, and iridium;

examples of a group 10 metal atom include nickel, palladium, and platinum;

examples of a group 11 metal atom include copper, silver, and gold;

examples of a group 12 metal atom include zinc, cadmium, and mercury;

examples of a group 13 metal atom include aluminum, gallium, indium, and thallium; and

examples of a group 14 metal atom include tin and lead.

Among these examples, the metal atom is preferably a metal atom belonging to any one of groups 8 to 11 in the periodic table, more preferably a metal atom belonging to any one of periods 4 and 5 among groups 9 to 11 in the periodic table, still more preferably cobalt, nickel, or copper, and particularly preferably copper.

Examples of the metal salt include salts of the metal atoms described above, and examples of the salts include: oxoacid salts such as a nitrate, a sulfate, a phosphate, a carboxylate, a perchlorate, a carbonate, and a borate; halides such as a thiocyanate, a sulfamate, a fluoride, a chloride, a bromide, and an iodide; and hydroxides. Examples of the carboxylate include a formate, an acetate, a propionate, a stearate, a naphthenate, a citrate, an oxalate, and a succinate.

Among these examples, a monocarboxylate, a nitrate, or a sulfate is preferable, a monocarboxylate having 1 to 6 carbon atoms is more preferable, and a formate, an acetate, or a propionate is further preferable.

Specific suitable examples of the metal salt include ruthenium formate, cobalt formate, nickel formate, copper formate, ruthenium acetate, cobalt acetate, nickel acetate, copper acetate, and hydrates of these salts.

The metal complex is a compound in which a metal atom is linked to a ligand by a coordinate bond. As the metal atom that forms the metal complex, the metal atoms contained in the metal salts described above can suitably be used.

Examples of the ligand include a monodentate ligand and a multidentate ligand.

Examples of the monodentate ligand include a hydroxo ligand, an amide ligand, a halogen ligand, an alkoxy ligand, an acyloxy ligand, a phosphine ligand, an amine ligand, and an ammonia ligand.

Examples of the amide ligand include an unsubstituted amide ligand (NH₂), a methylamide ligand (NHCH₃), a dimethylamide ligand (N(CH₃)₂), a diethylamide ligand (N(C₂H₅)₂), and a dipropylamide ligand (N(C₃H₇)₂).

Examples of the halogen ligand include a fluorine ligand, a chlorine ligand, a bromine ligand, and an iodine ligand.

Examples of the alkoxy ligand include a methoxy ligand, an ethoxy ligand, a propoxy ligand, and a butoxy ligand.

Examples of the acyloxy ligand include an acetoxy ligand, an ethylyloxy ligand, a butyryloxy ligand, a t-butyryloxy ligand, a t-amylyloxy ligand, an n-hexanecarbonyloxy ligand, and an n-octanecarbonyloxy ligand.

Examples of the amine ligand include a methylamine ligand, a dimethylamine ligand, a piperidine ligand, a morpholine ligand, and a pyridine ligand.

Examples of the phosphine ligand include a trimethylphosphine ligand, a triethylphosphine ligand, a tributylphosphine ligand, and a triphenylphosphine ligand.

Examples of the multidentate ligand include a ligand derived from a hydroxy acid ester, a ligand derived from a β-diketone, a ligand derived from a β-ketoester, a ligand derived from an α, α-dicarboxylic acid ester, a hydrocarbon having a π bond, and a diphosphine.

Examples of the hydroxy acid ester include a glycolic acid ester, a lactic acid ester, a 2-hydroxycyclohexane-1-carboxylic acid ester, and a salicylic acid ester.

Examples of the β-diketone include 2,4-pentanedione, 3-methyl-2,4-pentanedione, and 3-ethyl-2,4-pentanedione.

Examples of the β-ketoester include an acetoacetic acid ester, an α-alkyl-substituted acetoacetic acid ester, a β-ketopentanoic acid ester, a benzoylacetic acid ester, and a 1,3-acetonedicarboxylic acid ester.

Examples of the α, α-dicarboxylic acid ester include a malonic acid diester, an α-alkyl-substituted malonic acid diester, an α-cycloalkyl-substituted malonic acid diester, and an α-aryl-substituted malonic acid diester.

Examples of the hydrocarbon having a n bond include: chain dienes such as butadiene and isoprene; cyclic dienes such as cyclopentadiene, methylcyclopentadiene, pentamethylcyclopentadiene, cyclohexadiene, and norbornadiene; and aromatic hydrocarbons such as benzene, toluene, xylene, hexamethylbenzene, naphthalene, and indene.

Examples of the diphosphine include 1,1-bis(diphenylphosphino) methane, 1,2-bis(diphenylphosphino) ethane, 1,3-bis(diphenylphosphino) propane, 2,2′-bis(diphenylphosphino)-1,1′-binaphthyl, and 1,1′-bis(diphenylphosphino) ferrocene.

The ligand is preferably a multidentate ligand, more preferably a ligand derived from a β-diketone or a ligand derived from a β-ketoester, still more preferably a ligand derived from a β-ketoester, and particularly preferably a ligand derived from an acetoacetic acid ester.

Specific suitable examples of the metal complex include bisethylacetoacetate cobalt (II), bisethylacetoacetate nickel (II), trisethylacetoacetate ruthenium (III), bisacetylacetonate cobalt (II), bisacetylacetonate nickel (II), trisacetylacetonate ruthenium (III), and bisacetylacetonate copper (II).

The metal compounds described above may be used singly or in combination of two or more thereof. In terms of the conductivity of the metal-containing film, however, two or more metal compounds containing the same type of metal atom are preferably contained. Specifically, for example, two or more metal compounds containing the same type of metal atom but having different types of counterions or ligands are contained. In particular, preferred is use of two metal salts containing the same type of metal atom but having different types of counterions, more preferred is use of two metal salts containing the same type of metal atom but having two types of counterions at least one of which is a carboxylic acid ion, further preferred is use of two metal salts containing the same type of metal atom but having different types of carboxylic acid ions as counter ions, and particularly preferred is a combination of copper formate and copper acetate.

The lower limit of the content ratio of the metal compound is, relative to all the components contained in the composition for forming a metal-containing film, preferably 5 mass %, more preferably 10 mass %, and still more preferably 15 mass %. The upper limit of the content ratio is, relative to all the components contained in the composition for forming a metal-containing film, preferably 40 mass %, more preferably 30 mass %, and still more preferably 25 mass %. By setting the content ratio of the metal compound to the above range, the conductivity of the film can be improved.

### [Compound (I)]

The compound (I) is a compound that has an oxymethylene structure and generates an aldehyde structure when degraded through heating. The compound (I) is not particularly limited as long as the compound (I) is a compound that generates a reducing aldehyde structure when degraded or depolymerized during heating of a coating film of the composition for forming a metal-containing film. The compound (I) is preferably a polymer or copolymer having an oxymethylene structure, or a cyclic oligomer having an oxymethylene structure. Examples of the (homo) polymer having an oxymethylene structure include polyoxymethylene ([—CH₂—O-]ₛ). The value s is not particularly limited, and can be set in a range of 10 or more and 10000 or less in terms of the type and the amount of the metal compound and the flowability of the composition for forming a metal-containing film. Examples of the copolymer having an oxymethylene structure include a (block) copolymer of polyoxymethylene and polyoxyethylene ([—CH₂—O-]ₜ [—CH₂—CH₂O-]^{u}). As the value t, the same value as the value s of the homopolymer can be used. The value u is not particularly limited, and can, similarly to the case of the homopolymer, be set in a range of 10 or more and 10000 or less in terms of the type and the amount of the metal compound and the flowability of the composition for forming a metal-containing film. Examples of the cyclic oligomer having an oxymethylene structure include compounds in which 3 to 8 oxymethylene structures form a ring, such as 1,3,5-trioxane as a cyclic trimer having an oxymethylene structure, 1,3,5,7-tetraoxane as a cyclic tetramer, and 1,3,5,7,9-pentaoxane as a cyclic pentamer. The composition for forming a metal-containing film may contain two or more compounds (I).

The lower limit of the content ratio of the compound (I) (the total amount when a plurality of compounds (I) are present) is, relative to 1 mol of the metal compound, preferably 0.01 mol, more preferably 0.02 mol, still more preferably 0.05 mol, and particularly preferably 0.08 mol. The upper limit of the content ratio is, relative to 1 mol of the metal compound, preferably 5 mol, more preferably 2 mol, still more preferably 1 mol, and particularly preferably 0.5 mol. By setting the content ratio of the compound (I) to the above range, the composition for forming a metal-containing film that gives a film having excellent conductivity can be obtained.

The compound (I) may by synthesized by a known method, or a commercially available product may be used as the compound (I). Typical synthetic methods are described below. The homopolymer described above can be synthesized by performing anionic polymerization of formaldehyde as a monomer in the presence of a catalyst. The copolymer described above can be synthesized through ring-opening polymerization performed by adding a cationic polymerization initiator to a mixture of 1,3,5-trioxane and ethylene oxide or 1,3-dioxolane. The cyclic oligomer described above can be synthesized by reacting formaldehyde under an acidic catalyst. The synthetic methods, however, are not limited to these typical methods, and other known methods can be used.

### [Nitrogen-Containing Organic Compound]

The composition for forming a metal-containing film preferably further contains a nitrogen-containing organic compound. The nitrogen-containing organic compound thus contained acts as a solubilizer or a fluidizer of the metal compound and enables further improvement of the conductivity of the metal-containing film formed from the composition for forming a metal-containing film.

The nitrogen-containing organic compound is not particularly limited as long as the nitrogen-containing organic compound is an organic compound containing a nitrogen atom. The nitrogen-containing organic compound, however, preferably has a structure in which a divalent nitrogen-containing group (—NR^{P}—) or a trivalent nitrogen atom (—N═) is inserted between carbon atoms constituting a chain hydrocarbon, a structure in which the hydrogen atoms contained in a chain hydrocarbon are partially or entirely substituted with a monovalent nitrogen-containing group (—NR^{Q}R^{R}), or a structure combining these structures.

As the chain hydrocarbon, a linear or branched chain hydrocarbon having 2 to 20 carbon atoms is preferable. Examples of such a hydrocarbon include: alkanes such as ethane, propane, n-butane, i-butane, n-pentane, isopentane, and neopentane; alkenes such as ethylene, propene, and butene; and alkynes such as acetylene, propyne, and butyne.

R^{P}, R^{Q}, and R^{R} are each independently a hydrogen atom or a substituted or unsubstituted monovalent hydrocarbon group having 1 to 20 carbon atoms.

In the present specification, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no ring structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed only of an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed only of an aromatic ring structure, and may contain an alicyclic structure or a chain structure as a part thereof).

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, a tert-butyl group, an n-pentyl group, an isopentyl group, and a neopentyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms include: cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

When R^{P}, R^{Q}, and R^{R} each have a substituent, examples of the substituent include: a monovalent chain hydrocarbon group having 1 to 10 carbon atoms; halogen atoms such as a fluorine atom, a chlorine atom, a bromine atom, and an iodine atom; alkoxy groups such as a methoxy group, an ethoxy group, and a propoxy group; alkoxycarbonyl groups such as a methoxycarbonyl group and an ethoxycarbonyl group; alkoxycarbonyloxy groups such as a methoxycarbonyloxy group and an ethoxycarbonyloxy group; acyl groups such as a formyl group, an acetyl group, a propionyl group, and a butyryl group; a cyano group; and a nitro group.

The nitrogen-containing organic compound preferably contains at least one group selected from the group consisting of a hydroxy group and an amino group. Due to an unshared electron pair of a hydroxy group or an amino group contained in the nitrogen-containing organic compound, the metal compound and the nitrogen-containing organic compound increases interactions therebetween, enabling further improvement of the conductivity of the metal-containing film obtained.

In particular, the nitrogen-containing organic compound is preferably a diamine compound. A chelate effect of a diamine structure for a metal atom of the metal compound enables solubilization of the metal compound, leading to promotion of fluidization of the composition for forming a metal-containing film and thus to further improvement of the conductivity of the metal-containing film obtained.

Examples of the nitrogen-containing organic compound include compounds represented by the following formulae.

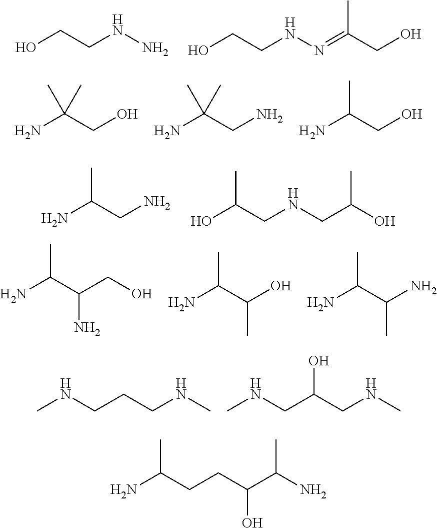

Various types of metal compounds (and metal atoms) can be used in combination with any nitrogen-containing organic compound, but when the metal atom is cobalt or nickel, the nitrogen-containing organic compound is preferably a hydrazine compound or a hydrazone compound. When the metal atom is copper, the nitrogen-containing organic compound is preferably a diamine compound or an amino alcohol compound.

The lower limit of the content ratio of the nitrogen-containing organic compound is, relative to 1 mol of the metal compound, preferably 0.1 mol, more preferably 0.5 mol, still more preferably 1 mol, and particularly preferably 1.5 mol. The upper limit of the content ratio is, relative to 1 mol of the metal compound, preferably 5 mol, more preferably 4 mol, still more preferably 3 mol, and particularly preferably 2.5 mol. By setting the content ratio of the nitrogen-containing organic compound to the above range, the conductivity of the film can be improved.

### [Solvent]

The solvent preferably contains an organic solvent. Examples of a solvent other than the organic solvent include water. The lower limit of the content ratio of the organic solvent accounting for in the solvent is preferably 40 mass %, more preferably 50 mass %, and still more preferably 60 mass %. The upper limit of the content ratio is preferably 100 mass % (the solvent contains only the organic solvent), but may be 99.9 mass % or may also be 99 mass %.

Examples of the organic solvent include an alcohol-based solvent, a ketone-based solvent, an ether-based solvent, an ester-based solvent, and a nitrogen-containing solvent. The composition for forming a metal-containing film can contain at least one organic solvent.

Examples of the alcohol-based solvent include: monoalcohol-based solvents such as methanol, ethanol, and n-propanol; and polyhydric alcohol-based solvents such as ethylene glycol, 1,2-propylene glycol, triethylene glycol, and tripropylene glycol.

Examples of the ketone-based solvent include: chain ketone-based solvents such as methyl ethyl ketone and methyl isobutyl ketone; and cyclic ketone-based solvents such as cyclohexanone.

Examples of the ether-based solvent include: chain ether-based solvents such as n-butyl ether; polyhydric alcohol ether-based solvents such as a cyclic ether-based solvent (e.g., tetrahydrofuran and 1,4-dioxane); and polyhydric alcohol partial ether-based solvents such as propylene glycol monoethyl ether, tripropylene glycol monomethyl ether, and tetraethylene glycol monomethyl ether.

Examples of the ester-based solvent include: carbonate-based solvents such as diethyl carbonate; acetic acid monoester-based solvents such as methyl acetate and ethyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the nitrogen-containing solvent include: chain nitrogen-containing solvents such as N, N-dimethylacetamide; and cyclic nitrogen-containing solvents such as N-methylpyrrolidone.

The solvent is preferably an alcohol-based solvent, an ether-based solvent, or an ester-based solvent, more preferably a polyhydric alcohol-based solvent, a polyhydric alcohol partial ether-based solvent, a lactic acid ester-based solvent, or a combination of the solvents, and still more preferably propylene glycol, propylene glycol monoethyl ether, propylene glycol monomethyl ether, or ethyl lactate.

The lower limit of the content of the solvent accounting for in the total mass of the composition for forming a metal-containing film is preferably 30 mass %, more preferably 40 mass %, and still more preferably 50 mass %. The upper limit of the content is preferably 80 mass %, more preferably 70 mass %, and still more preferably 60 mass %. By setting the content of the solvent to the above range, the flowability of the composition can be controlled and the film can exhibit high-level conductivity.

### [Other Optional Components]

The composition for forming a metal-containing film may contain, for example, an acid generator, a macromolecular additive, or a surfactant as a component other than the metal compound, the compound (I), and the solvent.

The acid generator is a compound that generates an acid through radiation irradiation and/or heating. The composition for forming a metal-containing film can contain at least one acid generator.

Examples of the acid generator include an onium salt compound and an N-sulfonyloxyimide compound.

The composition for forming a metal-containing film can further enhance the coatability to a substrate and an organic underlayer film and the continuity of the film by containing a macromolecular additive. The composition for forming a metal-containing film can contain at least one macromolecular additive.

Examples of the macromolecular additive include a fluorine-containing macromolecular compound, and a non-fluorine-based macromolecular compound.

Examples of the fluorine-containing macromolecular compound include compounds described in JP-A-2011-89090. Examples of the fluorine-containing macromolecular compound include compounds containing a repeating unit derived from a (meth) acrylate compound having a fluorine atom and a repeating unit derived from a (meth) acrylate compound having 2 or more (preferably 5 or more) alkyleneoxy groups (preferably ethyleneoxy groups or propyleneoxy groups).

Examples of the non-fluorine-based macromolecular compound include compounds containing at least one repeating unit derived from a (meth) acrylate monomer such as a linear or branched alkyl (meth) acrylate (e.g., lauryl (meth) acrylate, 2-ethylhexyl (meth) acrylate, n-butyl (meth) acrylate, t-butyl (meth) acrylate, isooctyl (meth) acrylate, isostearyl (meth) acrylate, and isononyl (meth) acrylate); an alkoxyethyl (meth) acrylate (e.g., methoxyethyl (meth) acrylate); an alkylene glycol di(meth) acrylate (e.g., ethylene glycol di(meth) acrylate and 1,3-butylene glycol di(meth) acrylate); a hydroxyalkyl (meth) acrylate (e.g., 2-hydroxyethyl (meth) acrylate, 2-hydroxypropyl (meth) acrylate, 2-hydroxybutyl (meth) acrylate, and 4-hydroxybutyl (meth) acrylate); dicyclopentenyloxyethyl (meth) acrylate; and nonylphenoxy polyethylene glycol (having a —(CH₂CH₂O)ₙ— structure, n=1 to 17) (meth) acrylate.

The composition for forming a metal-containing film can further enhance the coatability to a substrate and an organic underlayer film and the continuity of the film by containing a surfactant. The composition for forming a metal-containing film can contain at least one surfactant.

Examples of a commercially available product of the surfactant include “Newcol 2320”, “Newcol 714-F”, “Newcol 723”, “Newcol 2307”, and “Newcol 2303” (which are all manufactured by NIPPON NYUKAZAI CO., LTD.), “Pionin D-1107-S”, “Pionin D-1007”, “Pionin D-1106-DIR”, “Newkalgen TG310”, “Pionin D-6105-W”, “Pionin D-6112”, and “Pionin D-6512” (which are all manufactured by TAKEMOTO OIL & FAT Co., Ltd.), “SURFYNOL 420” “SURFYNOL 440”, “SURFYNOL 465”, and “SURFYNOL 2502” (which are all manufactured by Air Products and Chemicals, Inc.), “MEGAFACE F171”, “MEGAFACE F172”, “MEGAFACE F173”, “MEGAFACE F176”, “MEGAFACE F177”, “MEGAFACE F141”, “MEGAFACE F142”, “MEGAFACE F143”, “MEGAFACE F144”, “MEGAFACE R30”, “MEGAFACE F437”, “MEGAFACE F475”, “MEGAFACE F479”, “MEGAFACE F482”, “MEGAFACE F562”, “MEGAFACE F563”, “MEGAFACE F780”, “MEGAFACE R-40”, “MEGAFACE DS-21”, “MEGAFACE RS-56”, “MEGAFACE RS-90”, and “MEGAFACE RS-72-K” (which are all manufactured by DIC Corporation), “Fluorad FC430” and “Fluorad FC431” (which are all manufactured by Sumitomo 3M Limited), “AsahiGuard AG710”, “Surflon S-382”, “Surflon SC-101”, “Surflon SC-102”, “Surflon SC-103”, “Surflon SC-104”, “Surflon SC-105”, and “Surflon SC-106 (which are all manufactured by AGC Inc.), and “FTX-218” and “NBX-15” (manufactured by NEOS Co., Ltd.).

When the composition for forming a metal-containing film contains another optional component, the upper limit of the content of the other optional component (the total amount when a plurality of optional components are contained) is, relative to 100 parts by mass of the metal compound, preferably 10 parts by mass, and more preferably 5 parts by mass.

### <Method for Producing Composition for Forming a Metal-Containing Film>

The method for producing a composition for forming a metal-containing film includes mixing a metal compound, a compound (I), and a solvent (hereinafter, also referred to as a “mixing step”), wherein the metal compound is a metal salt or a metal complex, and the compound (I) is a compound that generates an aldehyde structure when degraded through heating.

As the metal compound, the compound (I), and the solvent used in the production method, the metal compound, the compound (I), and the solvent used in the composition for forming a metal-containing film can suitably be used.

In the mixing step, the composition for forming a metal-containing film is obtained by mixing the metal compound, the compound (I), and the solvent, and an optional component added as necessary at a prescribed ratio. Thereafter, preferably by filtering the resulting mixture with a 0.2-μm-or-less pore-diameter filter or the like, the composition can be produced.

### <Metal-Containing Film>

The metal-containing film according to the present embodiment is formed from a composition for forming a metal-containing film. The composition for forming a metal-containing film contains a metal compound, a compound (I), and a solvent. The metal compound is a metal salt or a metal complex, and the compound (I) is a compound that generates an aldehyde structure when degraded through heating.

As the composition for forming a metal-containing film to form the metal-containing film, the composition for forming a metal-containing film described above can suitably be used. The metal-containing film formed from the composition for forming a metal-containing film has excellent conductivity. Due to this property, the metal-containing film is suitable for the use as a resist underlayer film. The metal-containing film can more suitably be formed by a method for forming a metal-containing film described later.

The average thickness of the metal-containing film is not particularly limited and can be determined as appropriate. The lower limit of the average thickness of the metal-containing film is preferably 1 nm, more preferably 5 nm, and still more preferably 10 nm. The upper limit of the average thickness is preferably 10,000 nm, more preferably 7,000 nm, and still more preferably 5,000 nm. The average thickness of the metal-containing film can be defined as an average thickness obtained by observing a cross section of a metal-containing film-attached silicon substrate with a scanning electron microscope (“SU8220” of Hitachi High-Tech Corporation), measuring the film thickness at any three points, and calculating the average value of these values of the film thickness.

### <Method for Forming Metal-Containing Film>

The method, according to the present embodiment, for forming a metal-containing film includes directly or indirectly coating a substrate with a composition for forming a metal-containing film (hereinafter, also referred to as a “coating step”). The composition for forming a metal-containing film contains a metal compound, a compound (I), and a solvent, the metal compound is a metal salt or a metal complex, and the compound (I) is a compound that generates an aldehyde structure when degraded through heating.

As the composition for forming a metal-containing film used in the method for forming a metal-containing film, the composition for forming a metal-containing film described above can suitably be used. By using the composition for forming a metal-containing film, a metal-containing film having excellent conductivity can suitably be formed. The method for forming a metal-containing film may further include, after the coating step, heating a coating film formed in the coating step (hereinafter, also referred to as a “heating step”).

Hereinafter, the steps of the method for forming a metal-containing film is described.

### [Coating Step]

In this step, a substrate is directly or indirectly coated with a composition for forming a metal-containing film. Through this step, a coating film is formed directly or indirectly on the substrate. The coating method is not particularly limited, and can be performed by an appropriate method such as spin coating, cast coating, and roll coating. Examples of a case in which a substrate is indirectly coated with a composition for forming a metal-containing film include a case in which a substrate-surface modification film is formed on a substrate. The substrate-surface modification film is, for example, a film having a water contact angle different from the water contact angle of the coating film.

Examples of the substrate include a metal substrate, a silicon wafer, and a resin substrate. The “metal substrate” refers to a substrate containing a metal atom in at least a part of a surface layer thereof. The metal atom contained in the metal substrate is not particularly limited as long as the metal atom is an atom of a metal element. Examples of the metal atom do not include silicon and boron. Examples of the metal atom include copper, iron, zinc, cobalt, aluminum, tin, tungsten, zirconium, titanium, tantalum, germanium, molybdenum, ruthenium, gold, silver, platinum, palladium, and nickel. Examples of the metal substrate include a substrate made from a metal and a silicon wafer coated with a metal. The metal substrate may have formed in a part thereof a silicon nitride film, an alumina film, a silicon dioxide film, a tantalum nitride film, a titanium nitride film, or the like.

Examples of a resin that forms the resin substrate include a low-density polyethylene resin, a high-density polyethylene resin, an ABS resin (an acrylonitrile-butadiene-styrene copolymer), an acrylic resin, a styrene resin, a vinyl chloride resin, a polyester resin (e.g., polyethylene terephthalate (PET) and polyethylene naphthalate (PEN)), a polyacetal resin, a polysulfone resin, a polyether imide resin, a polyether ketone resin, and a cellulose derivative.

The substrate may be a substrate having no pattern formed thereon or may also be a substrate having a pattern formed thereon.

Examples of the pattern of the substrate having a pattern formed thereon include: a line and space pattern or a trench pattern having a space width of 2,000 nm or less, 1,000 nm or less, 500 nm or less, or further 50 nm or less; and a hole pattern having a diameter of 300 nm or less, 150 nm or less, 100 nm or less, or further 50 nm or less.

Examples of a dimension of the pattern formed on the substrate include a fine pattern having a height of 100 nm or more, 200 nm or more, or further 300 nm or more, a width of 50 nm or less, 40 nm or less, or further 30 nm or less, and an aspect ratio (height of pattern/width of pattern) of 3 or more, 5 or more, or further 10 or more.

When the substrate having a pattern formed thereon is used as the substrate, the coating film formed by coating the substrate with the composition for forming a metal-containing film preferably fills a recess of the pattern. For example, when the substrate having a pattern formed thereon is a metal substrate having a pattern of a low-dielectric insulating film (Low-k interlayer insulating film) formed in a part thereof, the coating film filling a recess of the pattern can form a conductive circuit. Examples of the low-dielectric insulating film include a silicon dioxide film, a carbon-doped silicon dioxide film, a fluorine-doped silicon dioxide film, and a boron phosphorus glass film.

After the composition for forming a metal-containing film is applied onto the substrate, drying may be performed as necessary. As a drying method, a conventionally known method can be used. The temperature of the drying is not particularly limited, but is preferably 50 to 100° C. The time of the drying is not also particularly limited, but is preferably 1 to 30 minutes.

### [Heating Step]

This step is an optional step of heating the coating film formed by the coating step. This step is considered to improve the conductivity of the coating film. Heating the coating film is considered to reduce a metal atom in the coating film and thus make the metal atom zerovalent, improving the conductivity of the metal-containing film.

An atmosphere for heating the coating film is preferably an atmosphere with an oxygen concentration of 30 ppm or less. The upper limit of the oxygen concentration is more preferably 25 ppm, still more preferably 20 ppm, and particularly preferably 10 ppm. The atmosphere is more preferable according as the oxygen concentration is low. The lower limit thereof is preferably 0 ppm, but may be 0.01 ppm or may also be 0.02 ppm. By heating the coating film in a low-oxygen-concentration atmosphere, improper oxidation of a metal atom in the coating film can be prevented, leading to promotion of the reduction and thus to the improvement of the conductivity of the metal-containing film.

As the atmosphere of the heating step, an inert or non-oxidizing gas is preferably used, and a nitrogen gas-containing atmosphere is more preferable. The use of such an atmosphere in the heating step can promote the reduction of a metal atom in the coating film.

The atmosphere of the heating step may further contain a hydrogen gas. By heating the coating film in an atmosphere containing a hydrogen gas, it is considered that the reduction of a metal atom in the coating film is further promoted and the conductivity of the metal-containing film is thus further improved. Particularly, when the metal atom is cobalt or nickel, introduction of a hydrogen gas into the atmosphere of the heating step can further promote the reduction of these metal atoms. When the metal atom is copper, the introduction of a hydrogen gas may be performed but is not necessary.

When the atmosphere of the heating step contains a hydrogen gas, the lower limit of the content ratio of the hydrogen gas accounting for in the atmosphere of the heating step is preferably 1000 ppm, more preferably 2000 ppm, still more preferably 5000 ppm, and particularly preferably 10000 ppm. The upper limit of the content ratio is preferably 100000 ppm, more preferably 80000 ppm, still more preferably 60000 ppm, and particularly preferably 40000 ppm. By setting the content ratio of the hydrogen gas to the above range, the reduction of a metal atom in the coating film is further promoted, enabling further improvement of the conductivity of the metal-containing film.

The atmosphere of the heating step may further contain water vapor. The atmosphere containing water vapor can further promote the reduction of a metal atom in the coating film. The introduction of water vapor can be performed by discharging a mixed gas containing a nitrogen gas and a hydrogen gas into ultrapure water and thus causing bubbling.

The lower limit of the temperature in the heating is preferably 150° ° C., more preferably 200° C., and still more preferably 220° C. The upper limit of the temperature is preferably 600° C., more preferably 500° C., and still more preferably 450° C. The lower limit of the time in the heating is preferably 100 seconds, more preferably 200 seconds, and still more preferably 300 seconds. The upper limit of the time is preferably 2,000 seconds, more preferably 1,000 seconds, and still more preferably 800 seconds.

Before the heating of the coating film, the coating film may be preliminarily heated at a temperature of 60° C. or more and 200° C. or less. The temperature of the preliminary heating is usually lower than the temperature of the heating. The lower limit of the time of the preliminary heating is preferably 10 seconds, and more preferably 30 seconds. The upper limit of the time is preferably 300 seconds, and more preferably 180 seconds. Examples of an atmosphere for heating the coating film include a nitrogen gas-containing atmosphere, a hydrogen gas-containing atmosphere, and an air atmosphere.

In the method for forming a metal-containing film, exposure and heating can be combined. A radiation to be used for the exposure is selected as appropriate from among electromagnetic waves such as a visible ray, an ultraviolet ray, a far ultraviolet ray, an X-ray, and a v-ray; and corpuscular rays such as an electron beam, a molecular beam, and an ion beam.

As the lower limit of the average thickness of the metal-containing film formed, the average thickness of the metal-containing film described above can suitably be used.

The metal-containing film may be disposed on the entire surface of the substrate or may also be disposed in the shape of a pattern. The pattern-shaped metal-containing film is useful as conductor wiring (wiring) of a printed circuit board or the like.

Examples of a method for obtaining a pattern-shaped metal-containing film include: a method for applying (coating) the composition for forming a metal-containing film described above to a substrate in the shape of a pattern, and performing the heating step described above; and a method for etching, in the shape of a pattern, a metal-containing film disposed on the entire surface of a substrate. The etching method is not particularly limited, and examples thereof include a subtractive method and a semi-additive method.

When the pattern-shaped metal-containing film is formed as a multi-layer wiring board, an insulating film (such as an insulating resin layer, an interlayer insulating film, and a solder resist) may further be stacked on the surface of the pattern-shaped metal-containing film, and wiring (a metal pattern) may further be formed on the surface of the insulating film.

A solder resist that is used to protect wiring and is one of materials for an insulating film is described in detail in, for example, JP-A-10-204150 and JP-A-2003-222993, and the materials described in the documents can be applied as desired. As the solder resist, a commercially available product may be used, and examples thereof include PFR800 and PSR4000 (trade names) manufactured by TAIYO INK MFG. CO., LTD. and SR7200G manufactured by Hitachi Chemical Co., Ltd.

### <Formation of Damascene Structure>

A metal-containing film (wiring layer) can be formed by coating the low-dielectric insulating film described above and having a pattern formed thereon with a composition for forming a metal-containing film to fill the pattern (wiring groove), and heating the coating film. Before the application of the composition for forming a metal-containing film, a barrier metal film may be formed. After the formation of the metal-containing film, a part of the metal-containing film can be removed through chemical mechanical polishing (CMP) to expose the surface of the low-dielectric insulating film and flatten the surface. The coating conditions and the heating conditions can be set similarly to the conditions of the coating step and the heating step in the method for forming a metal-containing film described above.

### EXAMPLES

Hereinafter, examples are described. The following examples merely illustrate typical examples of the present invention, and the examples should not be construed to narrow the scope of the present invention.

### <Preparation of Composition for Forming Metal-Containing Film>

A metal compound [A], a compound (I) [B], a nitrogen-containing organic compound [C], and a solvent [D] used in the preparation of a composition for forming a metal-containing film are described below.

### [Metal Compound [A]]

A-1: Cobalt (II) acetate tetrahydrate
A-2: Cobalt (II) formate dihydrate
A-3: Cobalt (II) sulfate heptahydrate
A-4: Cobalt (II) nitrate hexahydrate
A-5: Nickel (II) acetate tetrahydrate
A-6: Nickel (II) formate dihydrate
A-7: Nickel (II) sulfate hexahydrate
A-8: Nickel (II) nitrate hexahydrate
A-9: Copper (II) acetate tetrahydrate
A-10: Copper (II) formate dihydrate
A-11: Copper (II) sulfate pentahydrate
A-12: Copper (II) nitrate trihydrate

### [Compound (I) [B]]

B-1: Compound represented by the following formula (B-1)
B-2: Compound represented by the following formula (B-2)
B-3: Compound represented by the following formula (B-3)
B-4: Compound represented by the following formula (B-4)

### [Nitrogen-Containing Organic Compound [C]]

C-1: Compound represented by the following formula (C-1)
C-2: Compound represented by the following formula (C-2)
C-3: Compound represented by the following formula (C-3)
C-4: Compound represented by the following formula (C-4)
C-5: Compound represented by the following formula (C-5)
C-6: Compound represented by the following formula (C-6)
C-7: Compound represented by the following formula (C-7)

### [Solvent [D]]

D-1: Propylene glycol monoethyl ether
D-2: Propylene glycol

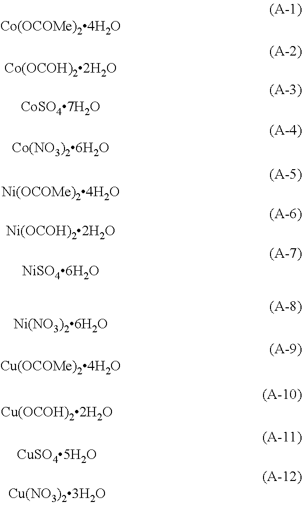

(In the formula, Me represents a methyl group.)

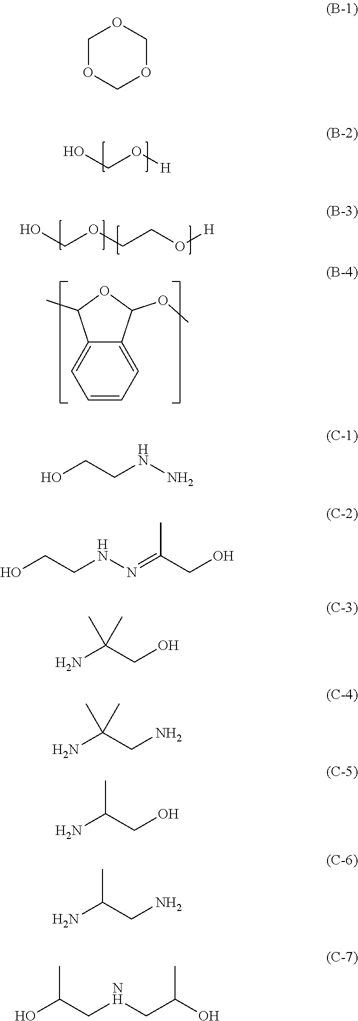

### [Example 1-1] Preparation of Composition (J-1) for Forming Metal-Containing Film

A composition (J-1) for forming a metal-containing film was prepared by mixing (A-1) (molar ratio 0.5) and (A-2) (molar ratio 0.5) as the metal compound [A], and (D-1) as the solvent [D] at such a ratio that the mass concentration of the metal atom of the metal compound [A]became 4 mass %, next mixing, with the mixture, (B-1) (molar ratio 0.1) as the compound (I) [B] and (C-1) (molar ratio 2) as the nitrogen-15 containing organic compound [C], and filtering the obtained solution with a 0.2-μm pore-diameter nylon syringe filter.

### Examples 1-2 to 1-33 and Comparative Examples 1-1 to 1-36

### Preparation of Compositions (J-2) to (J-33) and (j-1) to (j-36) for Forming Metal-Containing Film

Composition (J-2) to (J-33) for forming a metal-containing film of Examples 1-2 to 1-33 and compositions (j-1) 5 to (j-36) for forming a metal-containing film of Comparative Examples 1 to 36 were prepared in the same manner as in Example 1-1 except that the components were used in the types and the blending amounts shown in following Tables 1 and 2. The dash “-” in cells of the tables represents that the component was not used.

TABLE 1

| | | | | | | | | Nitrogen- | | |
|---|---|---|---|---|---|---|---|---|---|---|
| | | | | | | | | containing | | |
| | Composition | | | | | Compound (I) | | organic | | |
| | [J] for forming | Metal compound [A] | | | | [B] | | compound [C] | | Solvent |
| | metal- | | Molar | | Molar | | Molar | | Molar | [D] |
| | containing film | Type | ratio | Type | ratio | Type | ratio | Type | ratio | Type |
| Example 1-1 | J-1 | A-1 | 0.5 | A-2 | 0.5 | B-1 | 0.1 | C-1 | 2 | D-1 |
| Example 1-2 | J-2 | A-1 | 0.9 | A-3 | 0.1 | B-1 | 0.1 | C-1 | 2 | D-1 |
| Example 1-3 | J-3 | A-1 | 0.9 | A-4 | 0.1 | B-1 | 0.1 | C-1 | 2 | D-1 |
| Example 1-4 | J-4 | A-2 | 0.9 | A-3 | 0.1 | B-1 | 0.1 | C-1 | 2 | D-1 |
| Example 1-5 | J-5 | A-2 | 0.9 | A-4 | 0.1 | B-1 | 0.1 | C-1 | 2 | D-1 |
| Example 1-6 | J-6 | A-2 | 1.0 | — | — | B-1 | 0.1 | C-1 | 2 | D-1 |
| Example 1-7 | J-7 | A-5 | 0.5 | A-6 | 0.5 | B-1 | 0.1 | C-1 | 2 | D-1 |
| Example 1-8 | J-8 | A-5 | 0.9 | A-7 | 0.1 | B-1 | 0.1 | C-1 | 2 | D-1 |
| Example 1-9 | J-9 | A-5 | 0.9 | A-8 | 0.1 | B-1 | 0.1 | C-1 | 2 | D-1 |
| Example 1-10 | J-10 | A-6 | 0.9 | A-7 | 0.1 | B-1 | 0.1 | C-1 | 2 | D-1 |
| Example 1-11 | J-11 | A-6 | 0.9 | A-8 | 0.1 | B-1 | 0.1 | C-1 | 2 | D-1 |
| Example 1-12 | J-12 | A-6 | 1.0 | — | — | B-1 | 0.1 | C-1 | 2 | D-1 |
| Example 1-13 | J-13 | A-9 | 0.5 | A-10 | 0.5 | B-1 | 0.1 | C-3 | 2 | D-1 |
| Example 1-14 | J-14 | A-9 | 0.9 | A-11 | 0.1 | B-1 | 0.1 | C-3 | 2 | D-1 |
| Example 1-15 | J-15 | A-9 | 0.9 | A-12 | 0.1 | B-1 | 0.1 | C-3 | 2 | D-1 |
| Example 1-16 | J-16 | A-10 | 0.9 | A-11 | 0.1 | B-1 | 0.1 | C-3 | 2 | D-1 |
| Example 1-17 | J-17 | A-10 | 0.9 | A-12 | 0.1 | B-1 | 0.1 | C-3 | 2 | D-1 |
| Example 1-18 | J-18 | A-10 | 1.0 | — | — | B-1 | 0.1 | C-3 | 2 | D-1 |
| Example 1-19 | J-19 | A-1 | 0.5 | A-2 | 0.5 | B-1 | 0.1 | C-2 | 2 | D-1 |
| Example 1-20 | J-20 | A-5 | 0.5 | A-6 | 0.5 | B-1 | 0.1 | C-2 | 2 | D-1 |
| Example 1-21 | J-21 | A-9 | 0.5 | A-10 | 0.5 | B-1 | 0.1 | C-4 | 2 | D-1 |
| Example 1-22 | J-22 | A-9 | 0.5 | A-10 | 0.5 | B-1 | 0.1 | C-5 | 2 | D-1 |
| Example 1-23 | J-23 | A-9 | 0.5 | A-10 | 0.5 | B-1 | 0.1 | C-6 | 2 | D-1 |
| Example 1-24 | J-24 | A-9 | 0.5 | A-10 | 0.5 | B-1 | 0.1 | C-7 | 2 | D-1 |
| Example 1-25 | J-25 | A-1 | 0.5 | A-2 | 0.5 | B-2 | 0.1 | C-1 | 2 | D-1 |
| Example 1-26 | J-26 | A-1 | 0.5 | A-2 | 0.5 | B-3 | 0.1 | C-1 | 2 | D-1 |
| Example 1-27 | J-27 | A-5 | 0.5 | A-6 | 0.5 | B-2 | 0.1 | C-1 | 2 | D-1 |
| Example 1-28 | J-28 | A-5 | 0.5 | A-6 | 0.5 | B-3 | 0.1 | C-1 | 2 | D-1 |
| Example 1-29 | J-29 | A-9 | 0.5 | A-10 | 0.5 | B-2 | 0.1 | C-3 | 2 | D-1 |
| Example 1-30 | J-30 | A-9 | 0.5 | A-10 | 0.5 | B-3 | 0.1 | C-3 | 2 | D-1 |
| Example 1-31 | J-31 | A-1 | 0.5 | A-2 | 0.5 | B-1 | 0.1 | C-1 | 2 | D-2 |
| Example 1-32 | J-32 | A-5 | 0.5 | A-6 | 0.5 | B-1 | 0.1 | C-1 | 2 | D-2 |
| Example 1-33 | J-33 | A-9 | 0.5 | A-10 | 0.5 | B-1 | 0.1 | C-3 | 2 | D-2 |

TABLE 2

| | | | | | | | | Nitrogen- | | |
|---|---|---|---|---|---|---|---|---|---|---|
| | | | | | | | | containing | | |
| | Composition | | | | | Compound (I) | | organic | | |
| | [J] for forming | Metal compound [A] | | | | [B] | | compound [C] | | Solvent |
| | metal- | | Molar | | Molar | | Molar | | Molar | [D] |
| | containing film | Type | ratio | Type | ratio | Type | ratio | Type | ratio | Type |
| Comparative | j-1 | A-1 | 0.5 | A-2 | 0.5 | — | — | C-1 | 2 | D-1 |
| Example 1-1 | | | | | | | | | | |
| Comparative | j-2 | A-1 | 0.9 | A-3 | 0.1 | — | — | C-1 | 2 | D-1 |
| Example 1-2 | | | | | | | | | | |
| Comparative | j-3 | A-1 | 0.9 | A-4 | 0.1 | — | — | C-1 | 2 | D-1 |
| Example 1-3 | | | | | | | | | | |
| Comparative | j-4 | A-2 | 0.9 | A-3 | 0.1 | — | — | C-1 | 2 | D-1 |
| Example 1-4 | | | | | | | | | | |
| Comparative | j-5 | A-2 | 0.9 | A-4 | 0.1 | — | — | C-1 | 2 | D-1 |
| Example 1-5 | | | | | | | | | | |
| Comparative | j-6 | A-2 | 1 | — | — | — | — | C-1 | 2 | D-1 |
| Example 1-6 | | | | | | | | | | |
| Comparative | j-7 | A-5 | 0.5 | A-6 | 0.5 | — | — | C-1 | 2 | D-1 |
| Example 1-7 | | | | | | | | | | |
| Comparative | j-8 | A-5 | 0.9 | A-7 | 0.1 | — | — | C-1 | 2 | D-1 |
| Example 1-8 | | | | | | | | | | |
| Comparative | j-9 | A-5 | 0.9 | A-8 | 0.1 | — | — | C-1 | 2 | D-1 |
| Example 1-9 | | | | | | | | | | |
| Comparative | j-10 | A-6 | 0.9 | A-7 | 0.1 | — | — | C-1 | 2 | D-1 |
| Example 1-10 | | | | | | | | | | |
| Comparative | j-11 | A-6 | 0.9 | A-8 | 0.1 | — | — | C-1 | 2 | D-1 |
| Example 1-11 | | | | | | | | | | |
| Comparative | j-12 | A-6 | 1 | — | — | — | — | C-1 | 2 | D-1 |
| Example 1-12 | | | | | | | | | | |
| Comparative | j-13 | A-9 | 0.5 | A-10 | 0.5 | — | — | C-3 | 2 | D-1 |
| Example 1-13 | | | | | | | | | | |
| Comparative | j-14 | A-9 | 0.9 | A-11 | 0.1 | — | — | C-3 | 2 | D-1 |
| Example 1-14 | | | | | | | | | | |
| Comparative | j-15 | A-9 | 0.9 | A-12 | 0.1 | — | — | C-3 | 2 | D-1 |
| Example 1-15 | | | | | | | | | | |
| Comparative | j-16 | A-10 | 0.9 | A-11 | 0.1 | — | — | C-3 | 2 | D-1 |
| Example 1-16 | | | | | | | | | | |
| Comparative | j-17 | A-10 | 0.9 | A-12 | 0.1 | — | — | C-3 | 2 | D-1 |
| Example 1-17 | | | | | | | | | | |
| Comparative | j-18 | A-10 | 1 | — | — | — | — | C-3 | 2 | D-1 |
| Example 1-18 | | | | | | | | | | |
| Comparative | j-19 | A-1 | 0.5 | A-2 | 0.5 | — | — | C-2 | 2 | D-1 |
| Example 1-19 | | | | | | | | | | |
| Comparative | j-20 | A-5 | 0.5 | A-6 | 0.5 | — | — | C-2 | 2 | D-1 |
| Example 1-20 | | | | | | | | | | |
| Comparative | j-21 | A-9 | 0.5 | A-10 | 0.5 | — | — | C-4 | 2 | D-1 |
| Example 1-21 | | | | | | | | | | |
| Comparative | j-22 | A-9 | 0.5 | A-10 | 0.5 | — | — | C-5 | 2 | D-1 |
| Example 1-22 | | | | | | | | | | |
| Comparative | j-23 | A-9 | 0.5 | A-10 | 0.5 | — | — | C-6 | 2 | D-1 |
| Example 1-23 | | | | | | | | | | |
| Comparative | j-24 | A-9 | 0.5 | A-10 | 0.5 | — | — | C-7 | 2 | D-1 |
| Example 1-24 | | | | | | | | | | |
| Comparative | j-25 | A-1 | 0.5 | A-2 | 0.5 | — | — | C-1 | 2 | D-1 |
| Example 1-25 | | | | | | | | | | |
| Comparative | j-26 | A-1 | 0.5 | A-2 | 0.5 | — | — | C-1 | 2 | D-1 |
| Example 1-26 | | | | | | | | | | |
| Comparative | j-27 | A-5 | 0.5 | A-6 | 0.5 | — | — | C-1 | 2 | D-1 |
| Example 1-27 | | | | | | | | | | |
| Comparative | j-28 | A-5 | 0.5 | A-6 | 0.5 | — | — | C-1 | 2 | D-1 |
| Example 1-28 | | | | | | | | | | |
| Comparative | j-29 | A-9 | 0.5 | A-10 | 0.5 | — | — | C-3 | 2 | D-1 |
| Example 1-29 | | | | | | | | | | |
| Comparative | j-30 | A-9 | 0.5 | A-10 | 0.5 | — | — | C-3 | 2 | D-1 |
| Example 1-30 | | | | | | | | | | |
| Comparative | j-31 | A-1 | 0.5 | A-2 | 0.5 | — | — | C-1 | 2 | D-2 |
| Example 1-31 | | | | | | | | | | |
| Comparative | j-32 | A-5 | 0.5 | A-6 | 0.5 | — | — | C-1 | 2 | D-2 |
| Example 1-32 | | | | | | | | | | |
| Comparative | j-33 | A-9 | 0.5 | A-10 | 0.5 | — | — | C-3 | 2 | D-2 |
| Example 1-33 | | | | | | | | | | |
| Comparative | j-34 | A-1 | 0.5 | A-2 | 0.5 | B-4 | 0.1 | C-1 | 2 | D-1 |
| Example 1-34 | | | | | | | | | | |
| Comparative | j-35 | A-5 | 0.5 | A-6 | 0.5 | B-4 | 0.1 | C-1 | 2 | D-1 |
| Example 1-35 | | | | | | | | | | |
| Comparative | j-36 | A-9 | 0.5 | A-10 | 0.5 | B-4 | 0.1 | C-3 | 2 | D-1 |
| Example 1-36 | | | | | | | | | | |

### <Formation of Metal-Containing Film>

### Examples 2-1 to 2-43

The compositions (J-1) to (J-33) for forming a metal-containing film prepared above were each applied onto a silicon substrate by a spin coating method, using a spin coater (“MS-B200” manufactured by MIKASA CO., LTD.) under the conditions of 1,500 rpm and 30 seconds. A coating film obtained was heated using an RTA furnace (“QHC-P610CP” manufactured by ULVAC, Inc.) under the temperature, the atmosphere, and the time of the heating conditions shown in Table 3 below and cooled at 23ºC for 60 seconds. A film-attached silicon substrate was thus obtained.

For comparison, film-attached silicon substrates were obtained in the same procedure as described above, using the compositions (j-1) to (j-36) for forming a metal-containing film of Comparative Examples 1 to 36.

Atmospheres R-1, R-2, and R-3 shown in Table 3 are as follows.
R-1: Nitrogen gas
R-2: Mixed gas of 3% hydrogen gas and nitrogen gas
R-3: Humidified gas obtained by bubbling mixed gas of 3% hydrogen gas and nitrogen gas in ultrapure water

### <Evaluation>

The conductivity of the metal-containing films formed from the compositions for forming a metal-containing film prepared above was evaluated by the following method. Table 3 shows the evaluation results.

### [Conductivity]

The sheet resistance values (μΩ/sq) of the films of the film-attached silicon substrates in the examples and the comparative examples were measured using a resistivity measuring instrument (“Σ-5” manufactured by NPS, INC.) according to a direct current 4-point probe method. The specific resistivity (μΩ·cm) was calculated from the sheet resistance value (μΩ/sq) and the measurement value of the film thickness (nm) obtained by observing the cross-sectional shape of the film-attached silicon substrate with a scanning electron microscope (“SU8220” of Hitachi High-Tech Corporation). The conductivity was evaluated as [A] when the specific resistivity of the example was 15% or more lower than the specific resistivity of the metal-containing film for comparison, as [B] when lower in a range of 5% or more and less than 158, and as [C] when lower in a range of more than 0% and less than 5%.

TABLE 3

| | Composition | | Heating | | | |
|---|---|---|---|---|---|---|
| | for forming | | conditions | | | |
| | metal- | For | Temper- | | | Con |
| | containing | com- | ature | Atmos- | Time | duc- |
| | film | parison | [° C.] | phere | [min] | tivity |
| Example 2-1 | J-1 | j-1 | 400 | R-2 | 10 | B |
| Example 2-2 | J-1 | j-1 | 400 | R-3 | 10 | B |
| Example 2-3 | J-2 | j-2 | 400 | R-2 | 10 | B |
| Example 2-4 | J-3 | j-3 | 400 | R-2 | 10 | B |
| Example 2-5 | J-4 | j-4 | 400 | R-2 | 10 | B |
| Example 2-6 | J-5 | j-5 | 400 | R-2 | 10 | B |
| Example 2-7 | J-6 | j-6 | 400 | R-2 | 10 | B |
| Example 2-8 | J-1 | J-6 | 400 | R-2 | 10 | A |
| Example 2-9 | J-7 | j-7 | 400 | R-2 | 10 | B |
| Example 2-10 | J-7 | j-7 | 400 | R-3 | 10 | B |
| Example 2-11 | J-8 | j-8 | 400 | R-2 | 10 | B |
| Example 2-12 | J-9 | j-9 | 400 | R-2 | 10 | B |
| Example 2-13 | J-10 | j-10 | 400 | R-2 | 10 | B |
| Example 2-14 | J-11 | j-11 | 400 | R-2 | 10 | B |
| Example 2-15 | J-12 | j-12 | 400 | R-2 | 10 | B |
| Example 2-16 | J-7 | J-12 | 400 | R-2 | 10 | A |
| Example 2-17 | J-13 | j-13 | 250 | R-1 | 10 | B |
| Example 2-18 | J-13 | j-13 | 250 | R-2 | 10 | B |
| Example 2-19 | J-13 | j-13 | 250 | R-3 | 10 | B |
| Example 2-20 | J-14 | j-14 | 250 | R-1 | 10 | B |
| Example 2-21 | J-15 | j-15 | 250 | R-1 | 10 | B |
| Example 2-22 | J-16 | j-16 | 250 | R-1 | 10 | B |
| Example 2-23 | J-17 | j-17 | 250 | R-1 | 10 | B |
| Example 2-24 | J-18 | j-18 | 250 | R-1 | 10 | B |
| Example 2-25 | J-13 | J-18 | 250 | R-1 | 10 | A |
| Example 2-26 | J-19 | j-19 | 400 | R-2 | 10 | B |
| Example 2-27 | J-20 | j-20 | 400 | R-2 | 10 | B |
| Example 2-28 | J-21 | j-21 | 250 | R-1 | 10 | B |
| Example 2-29 | J-22 | j-22 | 250 | R-1 | 10 | B |
| Example 2-30 | J-23 | j-23 | 250 | R-1 | 10 | B |
| Example 2-31 | J-24 | j-24 | 250 | R-1 | 10 | B |
| Example 2-32 | J-25 | j-25 | 400 | R-2 | 10 | A |
| Example 2-33 | J-26 | j-26 | 400 | R-2 | 10 | A |
| Example 2-34 | J-27 | j-27 | 400 | R-2 | 10 | A |
| Example 2-35 | J-28 | j-28 | 400 | R-2 | 10 | A |
| Example 2-36 | J-29 | j-29 | 250 | R-1 | 10 | A |
| Example 2-37 | J-30 | j-30 | 250 | R-1 | 10 | A |
| Example 2-38 | J-31 | j-31 | 400 | R-2 | 10 | B |
| Example 2-39 | J-32 | j-32 | 400 | R-2 | 10 | B |
| Example 2-40 | J-33 | j-33 | 250 | R-1 | 10 | B |
| Example 2-41 | J-1 | j-34 | 400 | R-2 | 10 | C |
| Example 2-42 | J-7 | j-35 | 400 | R-2 | 10 | C |
| Example 2-43 | J-13 | j-36 | 250 | R-1 | 10 | C |

Table 3 shows the results in which the metal-containing films formed from the compositions for forming a metal-containing film of the examples had more excellent conductivity than the conductivity of the metal-containing films formed from the compositions for forming a metal-containing film of the comparative examples.

The composition, according to the present disclosure, for forming a metal-containing film enables formation of a metal-containing film having excellent conductivity. The method, according to the present disclosure, for forming a metal-containing film enables suitable formation of a metal-containing film having excellent conductivity. Accordingly, these disclosures can suitably be used to form a metal-containing film in a semiconductor field, a battery material field, and the like.

Obviously, numerous modifications and variations of the present invention (s) are possible in light of the above teachings. It is therefore to be understood that within the scope of the appended claims, the invention (s) may be practiced otherwise than as specifically described herein.

What is claimed is:

1. A composition comprising:
a metal compound;
a compound having an oxymethylene structure; and
a solvent,
wherein
the metal compound is a metal salt or a metal complex, and
the compound having an oxymethylene structure is capable of generating an aldehyde structure when degraded through heating.

2. The composition according to claim 1, wherein a metal atom contained in the metal compound belongs to any one of periods 3 to 7 among groups 2 to 14 in a periodic table.

3. The composition according to claim 2, wherein the metal atom is copper.

4. The composition according to claim 1, further comprising a nitrogen-containing organic compound.

5. The composition according to claim 4, wherein the nitrogen-containing organic compound comprises at least one group selected from the group consisting of a hydroxy group and an amino group.

6. The composition according to claim 4, wherein the nitrogen-containing organic compound is a diamine compound.

7. The composition according to claim 1, wherein
the solvent comprises an organic solvent which is a polyhydric alcohol-based solvent, a polyhydric alcohol partial ether-based solvent, a lactic acid ester-based solvent, or a combination thereof.

8. The composition according to claim 1, wherein the compound having an oxymethylene structure is a polymer or copolymer having the oxymethylene structure, or a cyclic oligomer having the oxymethylene structure.

9. The composition according to claim 1, wherein a content ratio of the compound having an oxymethylene structure in the composition is 0.01 mol or more and 5 mol or less relative to 1 mol of the metal compound.

10. The composition according to claim 1, wherein the metal compound comprises two or more metal compounds comprising a same metal atom.

11. A metal-containing film formed from the composition according to claim 1.

12. A method for forming a metal-containing film, comprising
applying a composition directly or indirectly onto a substrate to form a coating film,
wherein
the composition comprises: a metal compound; a compound having an oxymethylene structure; and a solvent,
the metal compound is a metal salt or a metal complex, and
the compound having an oxymethylene structure is capable of generating an aldehyde structure when degraded through heating.

13. The method according to claim 12, further comprising
heating the coating film in an atmosphere with an oxygen concentration of 30 ppm or less.

14. The method according to claim 13, wherein the atmosphere of the heating contains a nitrogen gas.

15. The method according to claim 13, wherein the atmosphere of the heating contains a hydrogen gas in an amount of 1000 ppm or more and 100000 ppm or less.

16. The method according to claim 13, wherein the atmosphere of the heating contains water vapor.

17. A method for producing a composition, comprising
mixing a metal compound, a compound having an oxymethylene structure, and a solvent,
wherein
the metal compound is a metal salt or a metal complex, and
the compound having an oxymethylene structure is capable of generating an aldehyde structure when degraded through heating.

18. The composition according to claim 1, wherein the compound having an oxymethylene structure is a copolymer having the oxymethylene structure.

19. The composition according to claim 1, wherein the compound having an oxymethylene structure is a cyclic oligomer having the oxymethylene structure.

20. The composition according to claim 1, wherein the metal compound is a metal complex.
